(19) United States
(12) Patent Application Publication
(10) Pub. No.: US 2026/0040933 A1
(43) Pub. Date: Feb. 5, 2026

(54) Semiconductor Device and Method of Making a Fan-Out Quilt Package

(71) Applicant: STATS ChipPAC Pte. Ltd., Singapore (SG)

(72) Inventors: DanFeng Yang, Jiangyin (CN); Kai Chong Chan, Singapore (SG); Swain Hong Alfred Yeo, Singapore (SG); Linda Pei Ee Chua, Singapore (SG)

(73) Assignee: STATS ChipPAC Pte. Ltd., Singapore (SG)

(21) Appl. No.: 18/790,239

(22) Filed: Jul. 31, 2024

(51) Int. Cl. H01L 23/528; H01L 21/56; H01L 23/14; H01L 23/31

(52) U.S. Cl. CPC H01L 23/5283; H01L 21/56; H01L 23/14; H01L 23/3157

(57) ABSTRACT

A semiconductor device has a substrate formed on a first carrier. A semiconductor die is mounted on the substrate. An interconnect structure is formed on a second carrier. A copper pillar is formed on the substrate or interconnect structure. The interconnect structure is disposed over the substrate with the copper pillar and semiconductor die between the substrate and interconnect structure. The first carrier and second carrier are removed after disposing the interconnect structure over the substrate. A system-in-package (SiP) is mounted to the substrate opposite the semiconductor die after removing the first carrier.

### FIELD OF THE INVENTION

The present invention relates in general to semiconductor devices and, more particularly, to semiconductor devices and methods of making fan-out quilt packages.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices may contain multiple electrical components, e.g., one or more semiconductor die and myriad discrete components to support the semiconductor die, disposed on one or more substrates to perform necessary electrical functions. Quilt packaging is a relatively new packaging technology that allows high integration of multiple semiconductor devices. However, existing quilt packaging methods and devices have significant downsides. Therefore, a need exists for improved semiconductor devices and methods of making fan-out quilt packages.

### BRIEF DESCRIPTION OF THE DRAWINGS

FIGS. 1a-1c illustrate a semiconductor wafer with a plurality of semiconductor die separated by a saw street;

FIGS. 2a-2l illustrate forming a quilt package with the semiconductor die;

FIGS. 3a-3d illustrate an optional third interconnect structure; and

FIGS. 4a and 4b illustrate an electronic device with the quilt packages.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

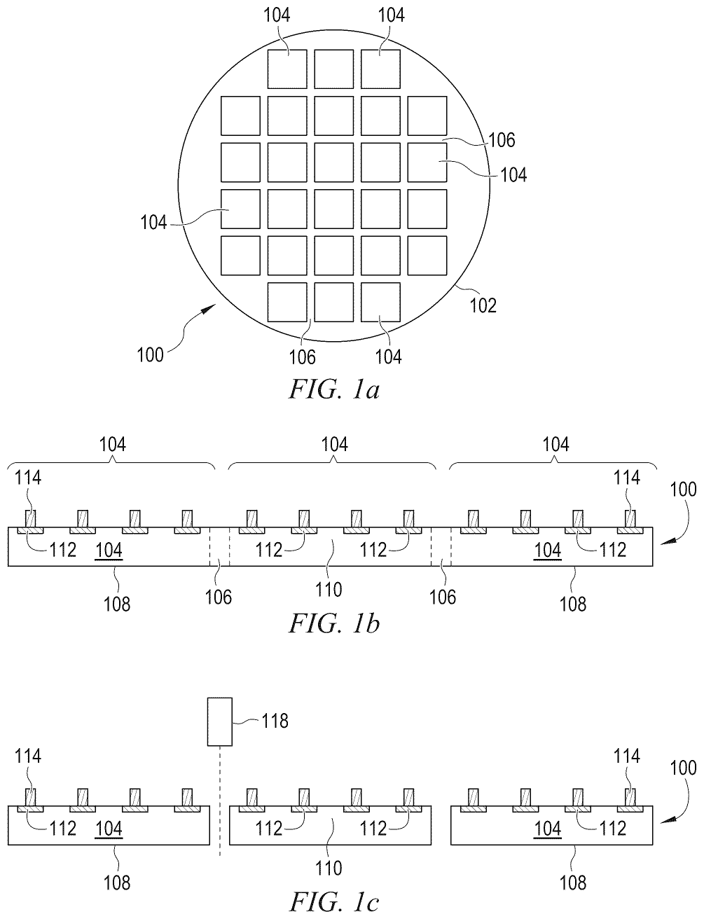

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, sputtering, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

Conductive microposts, microbumps, or micropillars 114 are formed on contact pads 112 of each semiconductor die 104 to provide external interconnection. Conductive micropillars 114 are typically formed by depositing conductive material into openings of a photolithographic mask layer and then removing the photolithographic mask layer. The material of micropillars 114 can be any of the materials mentioned herein for conductive layers, e.g., copper. In one embodiment, micropillars 114 have a copper core with a Ti/Cu plating 30 microns thick.

Micropillars 114 represent just one possible interconnect method. Other embodiments use bond wires, conductive paste, stud bumps, solder bumps, or any other suitable type of electrical interconnect. In some embodiments, an additional insulating or passivation layer is formed on active surface 110 around micropillars 114 with the micropillars extending above the insulating layer.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit after singulation.

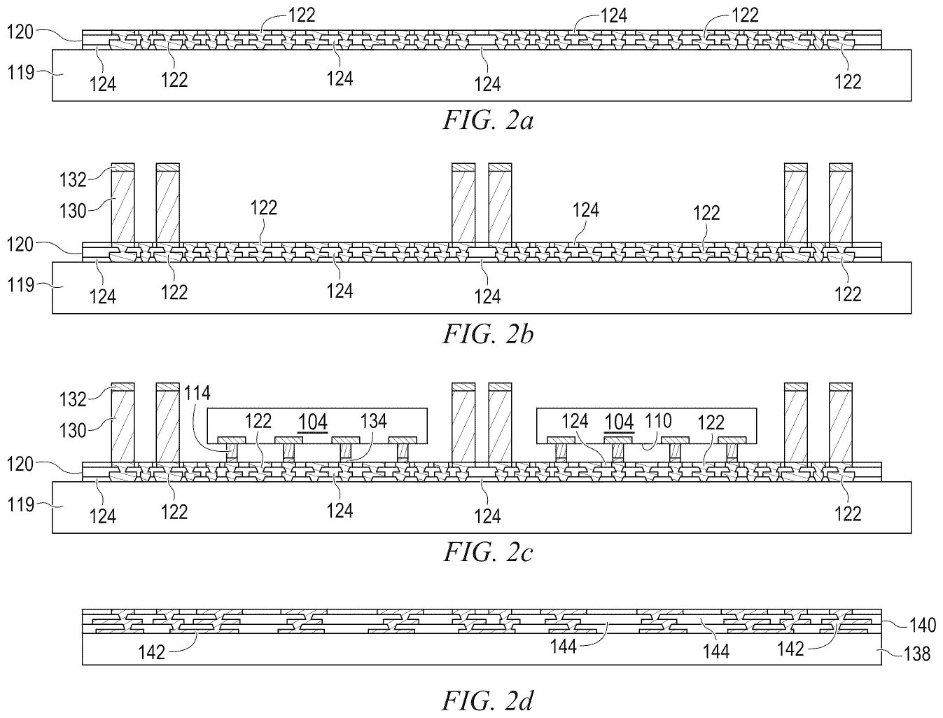

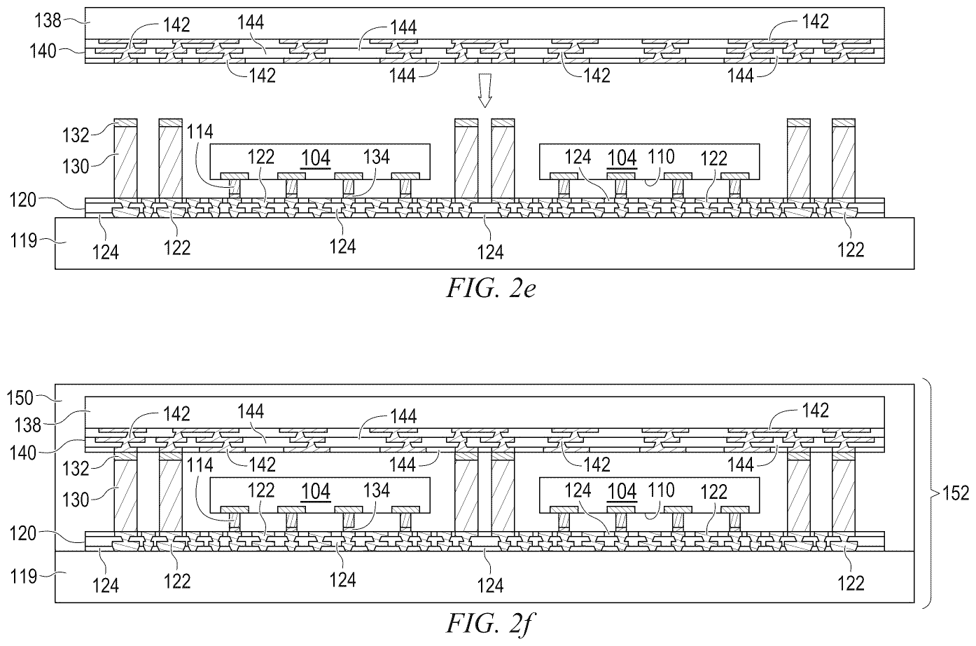

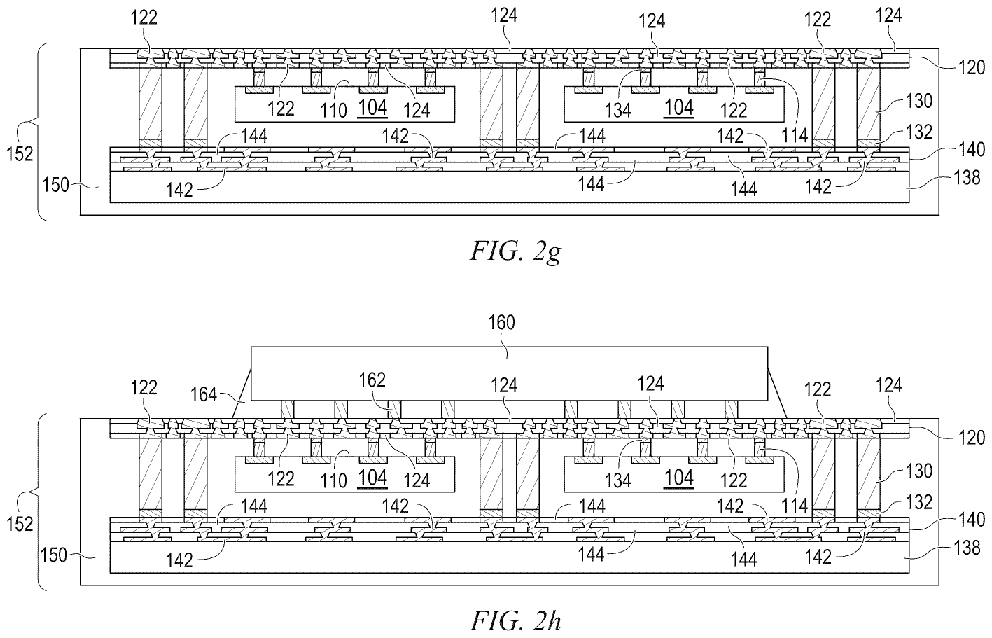

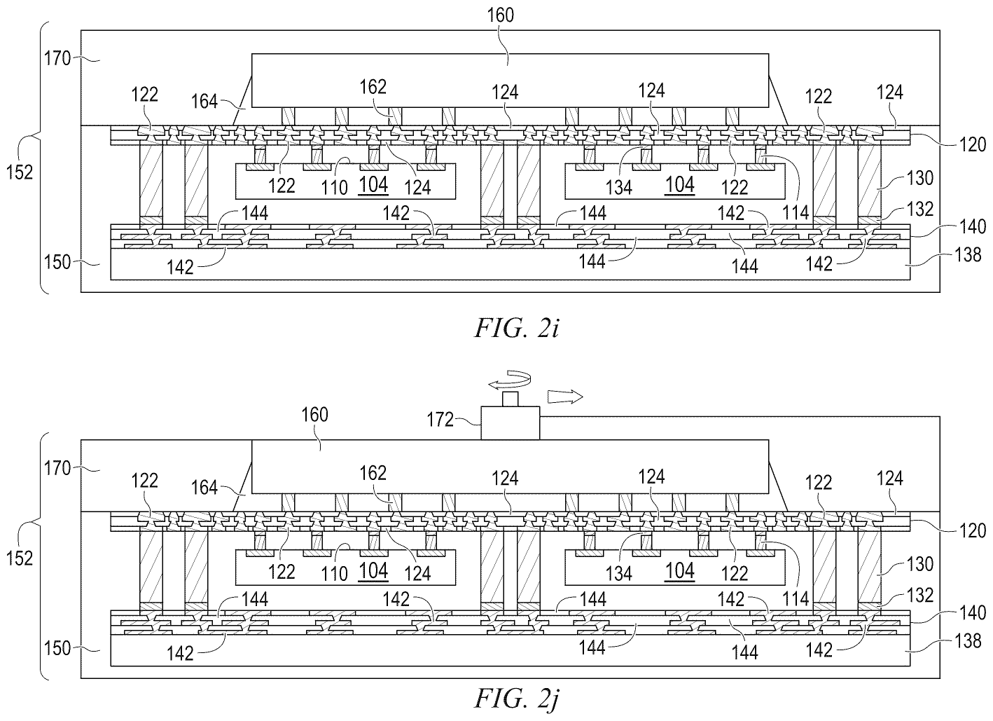

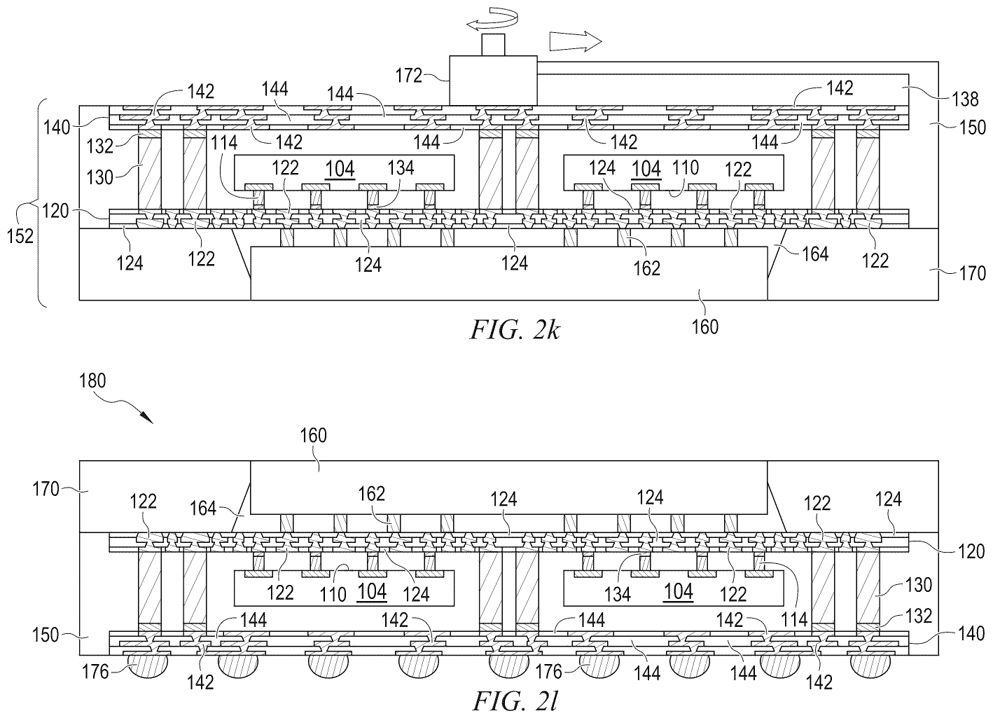

FIGS. 2a-2l illustrate forming a quilt package (QP) with semiconductor die 104. FIG. 2a shows a cross-sectional view of carrier 119 with an interposer, interconnect structure, or substrate 120 formed or disposed on the carrier. Carrier 119 can be a semiconductor substrate similar to wafer 100, an insulating board formed using any of the materials described herein for insulating layers, a sheet of conductive material, such as copper or aluminum, PCB material such as polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics, beryllium oxide, glass, or other suitable low-cost, rigid material for structural support.

Substrate 120 is formed on or attached to carrier 119 using a UV, laser, thermal or other type of releasable adhesive in some embodiments. The adhesive layer can be a liquid, tape, or other suitable form. Substrate 120 includes a plurality of conductive layers 122 and insulating layers 124 interleaved over each other. While only a single interposer 120 is shown, tens, hundreds, or thousands of interposers are commonly manufactured together in a single sheet or panel before being singulated from each other at the end of the illustrated process or at an intermediate step.

Conductive layer 122 can be one or more layers of Al, Cu, Sn, Ni, Au, Ag, or other suitable electrically conductive material. Conductive layers can be formed using PVD, CVD, electrolytic plating, electroless plating, or other suitable metal deposition process. Conductive layer 122 provides horizontal electrical interconnect across substrate 120 and vertical electrical interconnect between the top and bottom surfaces. Portions of conductive layer 122 can be electrically common or electrically isolated depending on the design and function of semiconductor die 104 and other electrical components. In the illustrated embodiments, conductive layers 122 are primarily comprised of conductive vias for vertical interconnect through substrate 120. In other embodiments, lateral signal routing is also provided by conductive traces formed as part of conductive layers 122.

Insulating layers 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Insulating layers 124 provide isolation between and structural support for conductive layers 122.

Any other suitable type of package substrate, interposer, or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Substrate 120 can also be a multi-layer flexible laminate, ceramic, copper clad laminate, glass, or semiconductor wafer including an active surface containing one or more transistors, diodes, and other circuit elements to implement analog circuits or digital circuits.

Conductive pillars 130 and solder caps 132 are formed on substrate 120 in FIG. 2b. Conductive pillars 130 are formed in a similar manner and with similar materials as disclosed for micropillars 114 and conductive layers 122 above. In one embodiment, conductive pillars 130 are formed by depositing conductive material into a photolithographic mask opening and then removing the mask. Conductive pillars 130 are formed on exposed contact pads of conductive layer 122. In some embodiments, an under-bump metallization is formed between conductive layer 122 and conductive pillars 130.

Solder caps 132 can be deposited into the same mask openings or otherwise printed or disposed onto the tops of pillars 130, e.g., using an evaporation, electrolytic plating, electroless plating, ball drop, or screen printing process. The material for solder caps 132 can be Al, Sn, Ni, Au, Ag, lead (Pb), bismuth (Bi), Cu, solder, and combinations thereof, with an optional flux solution. For example, the solder cap 132 material can be eutectic Sn/Pb, high-lead solder, or lead-free solder. Solder caps 132 can optionally be reflowed to form rounded bumps.

In FIG. 2c, semiconductor die 104 are disposed on substrate 120 between pillars 130 using a pick and place operation or other suitable means. Semiconductor die 104 are disposed with active surface 110 and micropillars 114 oriented toward substrate 120. A solder 134 is reflowed between conductive layer 122 and micropillar 114 to mechanically and electrically connect semiconductor die 104 to substrate 120. Solder 134 can be caps formed on micropillars 114 in a similar manner to caps 132 on pillars 130, solder paste printed on substrate 120, or any other suitable attachment and electrical connection means. An underfill is used between substrate 120 and semiconductor die 104 in some embodiments. Any other additional type of electrical components can be mounted onto substrate 120 as well, e.g., discrete active or passive components, other semiconductor die, subpackages, or chiplets.

FIG. 2d illustrates a cross-sectional view of carrier 138 with a second or top interconnect structure 140 formed or disposed on the carrier. Interconnect structure 140 is formed and structured similarly to substrate 120, with conductive layers 142 interleaved between insulating layers 144. In one embodiment, interconnect structure 140 is formed as part of a large panel of multiple attached interconnect structures and then singulated along with carrier 138 into the individual units shown in FIG. 2d. Interconnect structure 140 can be formed in a parallel process to the formation of substrate 120, which improves overall manufacturing time for the package being formed. Being manufactured in a parallel process means that substrates 120 and interconnect structures 140 can be formed at the same time on two different lines.

Conductive layers 142 are formed in substantially the same manner and using substantially the same materials as described above for conductive layers 122. Insulating layers 144 are formed in substantially the same manner and using substantially the same materials as described above for insulating layers 124. Any number of conductive and insulating layers can be formed interleaved over each other to form interconnect structure 140. Any other type of substrate or interposer, such as those mentioned above for substrate 120, can be used for interconnect structure 140 as well.

In FIG. 2e, interconnect structure 140 and carrier 138 are flipped and disposed over substrate 120 using a pick and place or other suitable operation. Conductive layers 142 of interconnect structure 140 have exposed contact pads that align to pillars 130. Interconnect structure 140 is set down with contact pads resting on solder caps 132. Solder caps 132 are reflowed to physically and electrically connect interconnect structure 140 to pillars 130 and thereby substrate 120. In some embodiments, a solder paste is plated onto substrate 140 instead of or in addition to having solder caps 132 on pillars 130. Pillars 130 and solder caps 132 are both formed on interconnect structure 140 instead of substrate 120 in other embodiments.

In FIG. 2f, an encapsulant or molding compound 150 is deposited over and around semiconductor die 104, substrate 120, pillars 130, and interconnect structure 140 using a paste printing, compression molding, transfer molding, liquid encapsulant molding, vacuum lamination, spin coating, or other suitable applicator. Encapsulant 150 can be liquid or granular polymer composite material, such as epoxy resin, epoxy acrylate, or another suitable polymer, with or without a filler. Encapsulant 150 is non-conductive, provides structural support, and environmentally protects the semiconductor device from external elements and contaminants.

Carrier 138 remains attached to interconnect structure 140 to support the interconnect structure during handling and molding. Encapsulant 150 optionally completely covers carrier 138. In some embodiments, substrate 120 remains as an unsingulated panel of multiple units during the molding stage. The encapsulated combination of carrier 119, substrate 120, carrier 138, and interconnect structure 140 forms a panel 152 of multiple attached units, where each unit looks approximately as shown in FIG. 2f.

In FIG. 2g, panel 152 is flipped with carrier 119 oriented upward or exposed. Carrier 119 is removed by mechanical peeling with an optional UV, thermal, or laser release. In other embodiments, carrier 119 is grinded away, chemically etched, or otherwise removed in a destructive manner. Removing carrier 119 exposes a surface of substrate 120 opposite semiconductor die 104.

In FIG. 2h, a semiconductor package, semiconductor die, chiplet, or system-in-package (SiP) 160 is flip-chip mounted onto the newly exposed surface of substrate 120. SiP 160 includes one or more semiconductor die and optionally a substrate or interposer to interconnect the semiconductor die with conductive pillars 162. Conductive pillars 162 are formed as described above for micropillars 114 and conductive pillars 130. A solder paste or cap is used to mechanically and electrically couple conductive pillars 162 to conductive layer 122 of substrate 120, as described above for caps 132 or solder 134. An optional underfill 164 is disposed between substrate 124 and SiP 160. In one embodiment, SiP 160 is a microprocessor packaged together with supporting devices such as a wireless transceiver, while semiconductor die 104 are external devices usable by the microprocessor, such as an IPM (e.g., QRAM) or flash memory. Any suitable device functionality is provided by SiP 160 and semiconductor die 104 in other embodiments.

A second encapsulant 170 is deposited over SiP 160 in FIG. 2i. Encapsulant 170 can be deposited in any of the methods, and using any of the materials, described above for encapsulant 150. Encapsulant 150 typically remains as a panel 152 with multiple units attached together when encapsulant 170 is deposited. Encapsulant 170 completely covers the top of SiP 160. In FIG. 2j, grinder 172 is used to remove a portion of encapsulant 170 and expose a back surface of SiP 160, thus making the top surface of SiP 160 coplanar to encapsulant 170. In other embodiments, SiP 160 is exposed by utilizing film-assisted molding, or another suitable process, so that encapsulant 170 is deposited without fully covering SiP 160. Having SiP 160 exposed is optional and allows a heatsink, thermal pad, or another thermal management solution to be in direct contact with the SiP.

In FIG. 2k, panel 152 is flipped so that carrier 138 is oriented upward or otherwise made available for backgrinding with grinder 172. Grinder 172 in FIG. 2k can be the same grinder as in FIG. 2j, or another grinder or other means of removing material can be used. Grinder 172 removes carrier 138 and a portion of encapsulant 150 to leave a surface of substrate 140 exposed.

An electrically conductive bump material is deposited over now-exposed contact pads of conductive layer 142 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 142 using a suitable attachment or bonding process. In one embodiment, the bump material is reflowed by heating the material above its melting point to form balls or bumps 176. In one embodiment, bump 176 is formed over an under-bump metallization (UBM) having a wetting layer, barrier layer, and adhesion layer. Bump 176 can also be compression bonded or thermocompression bonded to conductive layer 142. Bump 176 represents one type of interconnect structure that can be formed over conductive layer 142. The interconnect structure can also use bond wires, conductive paste, stud bump, micro bump, or other electrical interconnect. Removal of carrier 138 and bumping of interconnect structure 140 occurs prior to removal of carrier 119 and mounting of SiP 160 in some embodiments.

Panel 152 is singulated to separate each device into a separate QP 180 in FIG. 2l. QP 180 is a semiconductor package formed with an improved process flow that allows separate fabrication of the bottom and top interconnect structures, i.e., substrate 120 and interconnect structure 140. Interconnect structure 140 is flip-chip mounted onto substrate 120 after both are separately manufactured. The process flow allows flexibility such that substrate 120 can be of different size from interconnect structure 140. The illustrated process flow reduces processing time by allowing parallel processing of interconnect structure 140 and substrate 120.

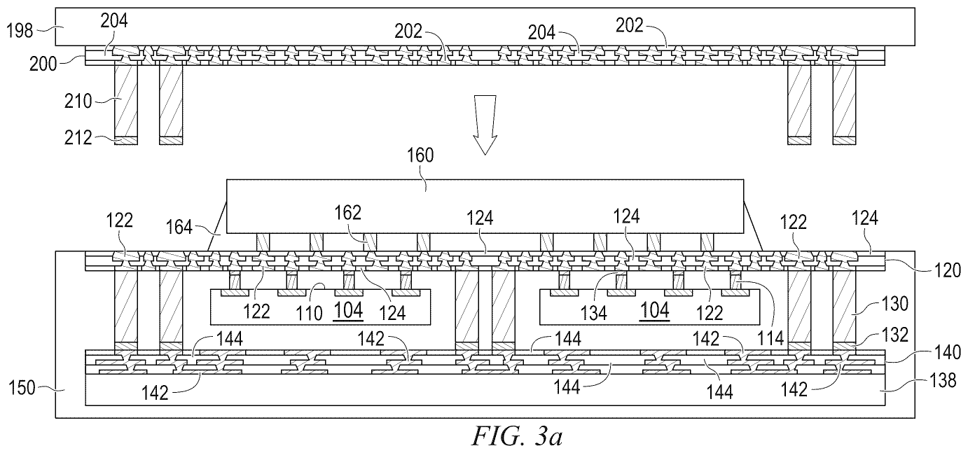

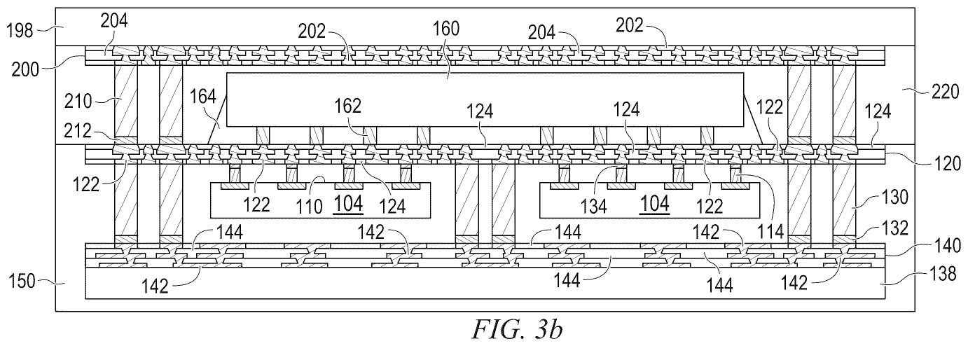

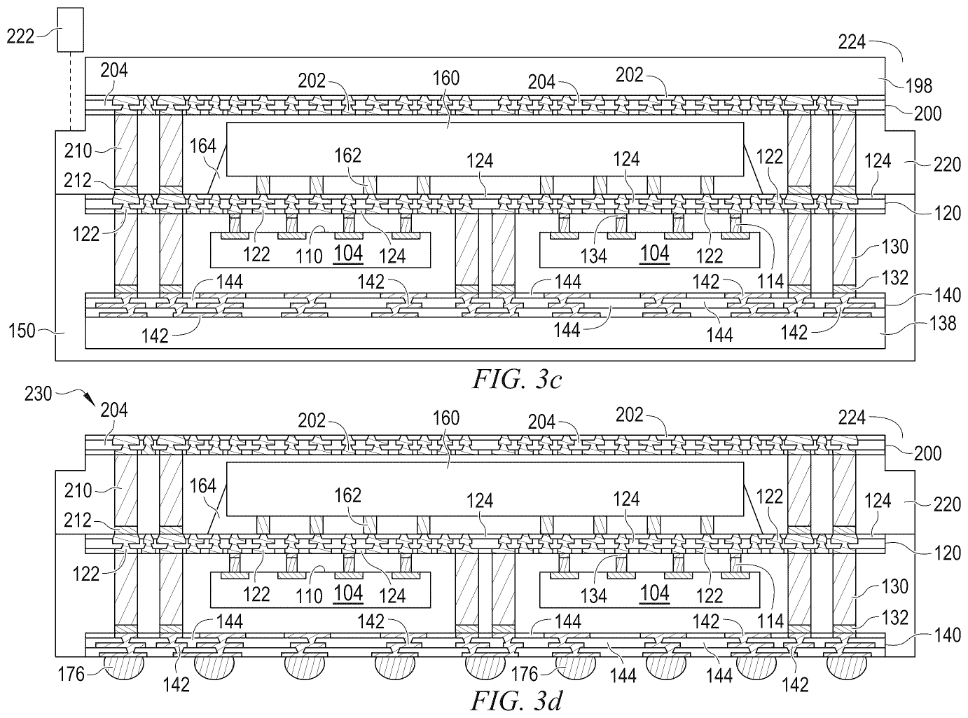

FIGS. 3a-3d illustrate the addition of a third interconnect structure over SiP 160. FIG. 3a continues from FIG. 2h. Interconnect structure 200 is formed or disposed on carrier 198 in substantially the same way as described above for interconnect structure 140. Interconnect structure 200 has a plurality of conductive layers 202 and insulating layers 204 interleaved over each other. Conductive pillars 210 and solder caps 212 are formed on interconnect structure 200 as described above for conductive pillars 130 and solder caps 132. In some embodiments, interconnect structure 200 is formed as a panel of multiple units and then singulated together with carrier 198. Interconnect structure 200 can be any type of substrate or interposer, such as those mentioned for substrate 120.

Interconnect structure 200 is flip-chip mounted onto substrate 120 over SiP 160 while still attached to carrier 198. Conductive pillars 210 and solder caps 212 are aligned to contact pads of conductive layer 122 around SiP 160. Solder caps 212 are reflowed to physically and electrically couple interconnect structure 200 and conductive pillars 210 to substrate 120.

FIG. 3b shows interconnect structure 200 attached to substrate 120. A gap remains between SiP 160 and interconnect structure 200. An encapsulant 220 is deposited between interconnect structure 200 and substrate 120 using the methods and materials described above for encapsulants 150 and 170. Encapsulant 220 optionally completely covers carrier 198 in some embodiments.

FIG. 3c shows an optional step of forming trenches 224 through carrier 198 and interconnect structure 200 using a laser or saw blade 222. Trenches 224 extend partially into encapsulant 220 and result in a step-cut extending completely around a perimeter of the package after singulation through the trench in FIG. 3d. Trenches 224 around carrier 198 make the carrier easier to remove by physically isolating the carrier from its surroundings. In some embodiments, carrier 198 remains as a large panel and trenches 224 allow the carrier to be removed as individual units instead of one large panel.

FIG. 3d shows a completed QP 230 after removing carriers 198 and 138 and forming bumps 176 on interconnect structure 140. QP 230 is a semiconductor package formed with a similar flow as QP 180 above, with all the same benefits, but with the addition of a third interconnect structure 200 over SiP 160. Interconnect structure 200 can be formed in a parallel process with both interconnect structure 140 and substrate 120. Interconnect structure 200 allows additional vertical integration or stacking and more advanced signal routing.

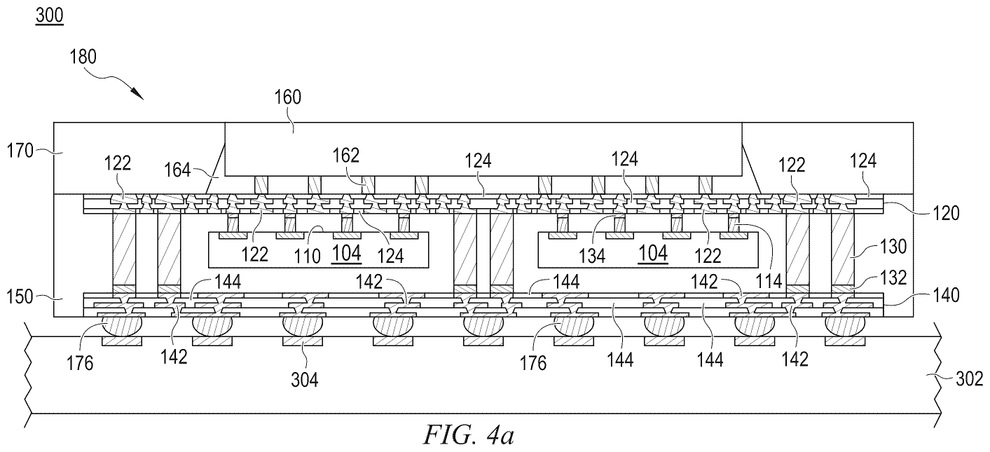

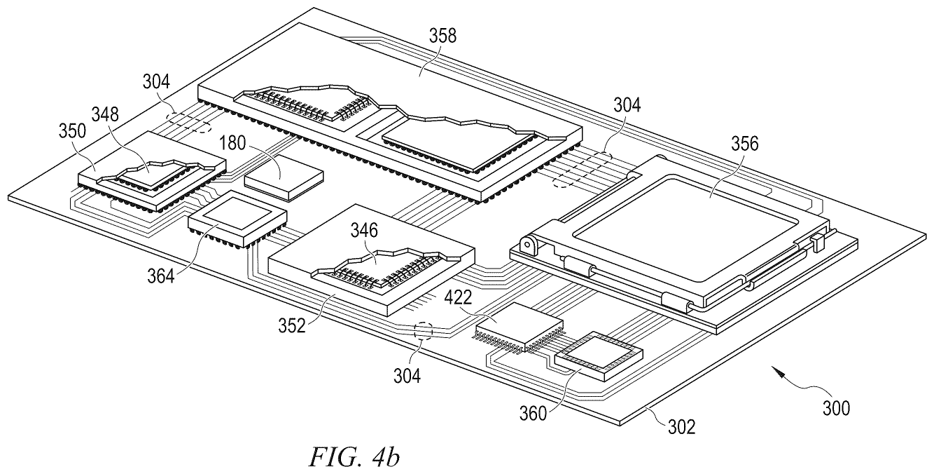

FIGS. 4a and 4b illustrate integrating the above-described semiconductor packages, e.g., QP 180, into a larger electronic device 300. FIG. 4a illustrates a partial cross-section of QP 180 mounted onto a printed circuit board (PCB) or other substrate 302 as part of electronic device 300. Solder bumps 176 are reflowed onto conductive layer 304 of PCB 302 to physically attach and electrically connect QP 180 to the PCB. In other embodiments, thermocompression or another suitable attachment and connection methods are used. In some embodiments, an adhesive or underfill layer is used between QP 180 and PCB 302. Semiconductor die 140 and SiP 160 are electrically coupled to conductive layer 304 through bumps 176, substrate 140, conductive pillars 130, and substrate 120.

FIG. 4b illustrates electronic device 300 having a chip carrier substrate or PCB 302 with a plurality of semiconductor packages disposed on a surface of PCB 302, including QP 180. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 4b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 446 and flipchip 448, are shown on PCB 302. Additionally, several types of second level packaging, including ball grid array (BGA) 450, bump chip carrier (BCC) 452, land grid array (LGA) 456, multi-chip module (MCM) or SIP module 458, quad flat non-leaded package (QFN) 460, quad flat package 462, and embedded wafer level ball grid array (eWLB) 464 are shown disposed on PCB 302. In one embodiment, eWLB 464 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims. The order of steps disclosed above can be rearranged unless a specific order has been described as necessary or recited in a claim. For instance, the various methods of protecting photonic circuit 110 can be applied after backgrinding wafer 100 and otherwise preparing the photonic die 104.

What is claimed:

1. A method of making a semiconductor device, comprising:
forming a substrate on a first carrier;
mounting a semiconductor die on the substrate;
forming an interconnect structure on a second carrier;
forming a copper pillar on the substrate or interconnect structure;
disposing the interconnect structure over the substrate with the copper pillar and semiconductor die disposed between the substrate and interconnect structure;
removing the first carrier and second carrier after disposing the interconnect structure over the substrate; and
mounting a system-in-package (SiP) to the substrate opposite the semiconductor die after removing the first carrier.

2. The method of claim 1, further including:
forming a second interconnect structure;
forming a second copper pillar on the second interconnect structure; and
mounting the second interconnect structure to the substrate over the SiP with the second copper pillar between the substrate and second interconnect structure.

3. The method of claim 2, further including:
depositing an encapsulant between the substrate and second interconnect structure; and
cutting only partially through the encapsulant.

4. The method of claim 1, further including depositing a first encapsulant between the interconnect structure and substrate.

5. The method of claim 4, further including depositing a second encapsulant over the SiP.

6. The method of claim 5, further including removing a portion of the second encapsulant to expose the SiP.

7. A method of making a semiconductor device, comprising:
forming a substrate;
mounting a semiconductor die on the substrate;
forming an interconnect structure;
forming a copper pillar on the substrate or interconnect structure;
disposing the interconnect structure over the substrate with the copper pillar and semiconductor die disposed between the substrate and interconnect structure; and
mounting a system-in-package (SiP) to the substrate opposite the semiconductor die.

8. The method of claim 7, further including:
forming a second interconnect structure;
forming a second copper pillar on the second interconnect structure; and
mounting the second interconnect structure to the substrate over the SiP with the second copper pillar between the substrate and second interconnect structure.

9. The method of claim 8, further including:
depositing an encapsulant between the substrate and second interconnect structure; and
cutting only partially through the encapsulant.

10. The method of claim 7, further including depositing a first encapsulant between the interconnect structure and substrate.

11. The method of claim 10, further including depositing a second encapsulant over the SiP.

12. The method of claim 11, further including removing a portion of the second encapsulant to expose the SiP.

13. The method of claim 7, further including forming the substrate and interconnect structure in parallel processes.

14. A method of making a semiconductor device, comprising:
forming a substrate;
mounting a semiconductor die on the substrate;
forming an interconnect structure;
disposing the interconnect structure over the substrate with the semiconductor die disposed between the substrate and interconnect structure; and
mounting a system-in-package (SiP) to the substrate opposite the semiconductor die.

15. The method of claim 14, further including depositing a first encapsulant between the interconnect structure and substrate.

16. The method of claim 15, further including depositing a second encapsulant over the SiP.

17. The method of claim 16, further including removing a portion of the second encapsulant to expose the SiP.

18. The method of claim 14, further including:
forming a second interconnect structure;
forming a second copper pillar on the second interconnect structure; and
mounting the second interconnect structure to the substrate over the SiP with the second copper pillar between the substrate and second interconnect structure.

19. The method of claim 18, further including:
depositing an encapsulant between the substrate and second interconnect structure; and
cutting only partially through the encapsulant.

20. A semiconductor device, comprising:
a substrate;
a semiconductor die mounted on the substrate;
an interconnect structure disposed over the substrate with the semiconductor die between the substrate and interconnect structure; and
a system-in-package (SiP) mounted to the substrate opposite the semiconductor die.

21. The semiconductor device of claim 20, further including a first encapsulant deposited between the interconnect structure and substrate.

22. The semiconductor device of claim 21, further including a second encapsulant deposited over the SiP.

23. The semiconductor device of claim 22, wherein the second encapsulant is coplanar to the SiP.

24. The semiconductor device of claim 20, further including:
a second interconnect structure; and
a second copper pillar formed on the second interconnect structure, wherein the second interconnect structure is mounted to the substrate over the SiP with the second copper pillar between the substrate and second interconnect structure.

25. The semiconductor device of claim 24, further including:
an encapsulant deposited between the substrate and second interconnect structure; and
a cut extending only partially through the encapsulant.
